(19) United States
(12) Patent Application Publication
(10) Pub. No.: US 2026/0247611 A1
(43) Pub. Date: Aug. 20, 2026

(54) VERTICAL CHANNEL TRANSISTOR STRUCTURE AND METHOD OF MANUFACTURING THE SAME

(71) Applicant: NANYA TECHNOLOGY CORPORATION, New Taipei City (TW)

(72) Inventor: Tseng-Fu Lu, New Taipei City (TW)

(73) Assignee: NANYA TECHNOLOGY CORPORATION, New Taipei City (TW)

(21) Appl. No.: 19/054,900

(22) Filed: Feb. 16, 2025

(51) Int. Cl. H10B 12/00

(52) U.S. Cl. CPC H10B 12/488; H10B 12/01

(57) ABSTRACT

A vertical channel transistor structure includes oxide semiconductor pillars, a first electrode, a second electrode, word lines and a gate oxide layer. Each of the oxide semiconductor pillars has a top end and a bottom end. The first electrode is disposed under and connected to the top end of each of the oxide semiconductor pillars, and the second electrode is disposed on and connected to the bottom end of each of the oxide semiconductor pillars. The word lines are disposed at different heights of the oxide semiconductor pillars. The gate oxide layer is dispose between each of the oxide semiconductor pillars and each of the word lines.

### BACKGROUND

### Technical Field

The disclosure relates to a semiconductor device, and particularly relates to a vertical channel transistor structure and a method of manufacturing the same.

### Description of Related Art

To continue DRAM roadmap below 10 nm, the 4F² unit cell structure with vertical channel/pillar transistor (VCT/VPT) is proposed to replace the 6F² unit cell structure for high density and low cost requirements.

However, the interference from adjacent WL is the weakness of this VCT/VPT transistor in 4F² DRAM, and it causes the RETH issue after frequent operation of adjacent WLs. Therefore, it causes the difficulty for 4F² DRAM unit cell dimension shrinkage for next generation due to this smaller WL-WL spacing (worse coupling effect).

### SUMMARY

The disclosure provides a vertical channel transistor structure and a method of manufacturing the same to reduce the WL-WL coupling effect and to increase the feasibility of unit cell dimension shrinkage in 4F² DRAM.

The vertical channel transistor structure of the disclosure includes a plurality of oxide semiconductor pillars, a first electrode, a second electrode, a plurality of word lines and a gate oxide layer. Each of the plurality of oxide semiconductor pillars has a top end and a bottom end. The first electrode is disposed under and connected to the bottom end of each of the plurality of oxide semiconductor pillars. The second electrode is disposed on and connected to the top end of each of the plurality of oxide semiconductor pillars. The plurality of word lines are disposed at different heights of the plurality of oxide semiconductor pillars. The gate oxide layer is disposed between each of the plurality of oxide semiconductor pillars and each of the plurality of word lines.

In an embodiment of the disclosure, one of the word lines is disposed at different height of the oxide semiconductor pillars with another one of the word lines close to the one of the word lines.

In an embodiment of the disclosure, a minimum distance between the one of the word lines and the another one of the word lines is longer than a horizontal distance between the one of the word lines and the another one of the word lines.

In an embodiment of the disclosure, in a cross-sectional view, a shape of each of the plurality of word lines is a trapezoid.

In an embodiment of the disclosure, in a cross-sectional view, a shape of each of the plurality of oxide semiconductor pillars is an inverted trapezoid.

In an embodiment of the disclosure, one of the plurality of word lines surrounds a group of the plurality of oxide semiconductor pillars along a direction parallel to a plane, and the plurality of oxide semiconductor pillars are disposed vertically to the plane.

The method of manufacturing a vertical channel transistor structure of the disclosure includes following steps. A plurality of first electrodes is formed on a substrate, and a first word line is formed at a first height over the first electrode. A second word line is formed at a second height over the first electrode, wherein the first height is different form the second height. A plurality of channel holes are formed to penetrate the first word line and the second word line respectively. A gate oxide layer is formed at a sidewall of each of the plurality of channel holes. A plurality of oxide semiconductor pillars is formed in the plurality of channel holes. A plurality of second electrodes is formed on the plurality of oxide semiconductor pillars respectively.

In another embodiment of the disclosure, the first height is higher than the second height, or the first height is shorter than the second height.

In another embodiment of the disclosure, a method of forming the first word line includes forming a first insulation layer on the plurality of first electrodes, depositing a conductive material layer on the first insulation layer, forming a first patterned mask on the conductive material layer, and etching back the conductive material layer using the first patterned mask as an etching mask.

In another embodiment of the disclosure, a method of forming the second word line includes forming a second insulation layer over the first word line, depositing a conductive material layer on the second insulation layer, forming a second patterned mask on the conductive material layer, and etching back the conductive material layer using the second patterned mask as an etching mask.

In another embodiment of the disclosure, a method of forming the plurality of channel holes includes forming a third insulation layer on the second word line, forming a third patterned mask on the third insulation layer, and etching the third insulation layer, the second word line and the first word line using the third patterned mask as an etching mask until the first electrodes are exposed.

In another embodiment of the disclosure, the third patterned mask has a first opening aligned with the first word line.

In another embodiment of the disclosure, the third patterned mask has a second opening aligned with the second word line.

Based on the above, according to the vertical channel transistor structure of the disclosure, the word lines are disposed at different height, and thus the WL-WL coupling effect may be reduced; meanwhile, the feasibility of unit cell dimension shrinkage in 4F² DRAM may be increased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a plan view of a plurality of vertical channel transistor structures in accordance with some embodiments of the present disclosure.

FIG. 2 illustrates a cross-sectional view of the vertical channel transistor structures of FIG. 1.

FIG. 3 illustrates a cross-sectional view of a vertical channel transistor structures in accordance with some embodiments of the present disclosure.

FIG. 4A through FIG. 4H are cross-sectional views of a process for the manufacture of a vertical channel transistor structure in accordance with some embodiments of the present disclosure.

### DESCRIPTION OF THE EMBODIMENTS

With reference to the drawings attached, the disclosure will be described by means of the embodiments below. Nevertheless, the disclosure may be embodied in many different forms and should not be construed as limited to the embodiments set forth herein. In the drawings, for the purpose of clarity and specificity, the sizes and the relative sizes of each layer and region may not be illustrated in accurate proportion.

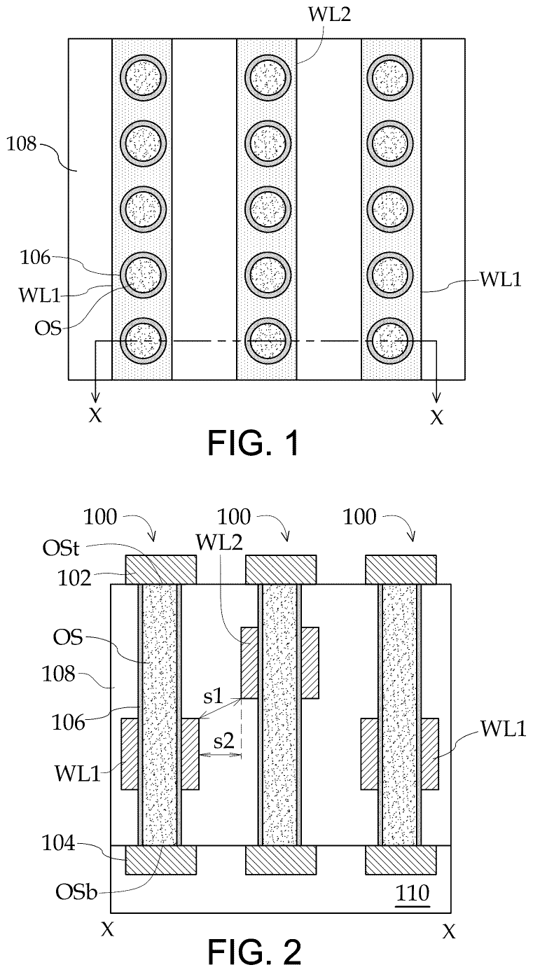

FIG. 1 illustrates a plan view of a plurality of vertical channel transistor structures in accordance with some embodiments of the present disclosure, and FIG. 2 illustrates a cross-sectional view taken along X-X of FIG. 1. For clarity, some elements in FIG. 1 are not shown such as the first electrode 104 and an upper portion of the insulation layer 108 in FIG. 2.

Referring now to FIGS. 1 and 2, each vertical channel transistor structure 100 includes a plurality of oxide semiconductor pillars OS, a first electrode 102, a second electrode 104, a plurality of word lines WL1-WL2 and a gate oxide layer 106. Each of the oxide semiconductor pillars OS has a top end OSt and a bottom end OSb. The first electrode 104 is disposed under and connected to the bottom end OSb of each of the oxide semiconductor pillars OS. The second electrode 102 is disposed on and connected to the top end OSt of each of the oxide semiconductor pillars OS. In some embodiments, the oxide semiconductor pillars OS are vertically disposed over a substrate 110. In some embodiments, a material of the oxide semiconductor pillars OS may be at least one of indium gallium zinc oxide (IGZO), manganese oxide (MnO₂), zinc oxide (ZnO), indium zinc oxide (IZO), indium tin zinc oxide (ITZO) and the like, and no limitation is made to the present disclosure herein.

The word lines WL1-WL2 are disposed at different heights of the oxide semiconductor pillars OS. The term “height” in this embodiments may also refer to a vertical distance from the same object such as a substrate 110 or the second electrode 104. In other words, the word lines WL1-WL2 can be regarded as double deck WLs. In some embodiments, one of the word lines (e.g. the word line WL1) is disposed at different height of the oxide semiconductor pillars OS with another one (e.g. the word line WL2) of the word lines close to the one (the word line WL1) of the word lines. In some embodiments, a minimum distance s1 between the word line WL1 and the word line WL2 is longer than a horizontal distance s1 between the word line WL1 and the word line WL2. The horizontal distance s1 is a spacing between the word line WL1 and the word line WL2 along X-X line. In this disclosure, the word line WL1 and the word line WL2 are disposed at different height, and thus the distance therebetween may be increased for reducing the WL-WL coupling (adjacent WL interference) effect, or the feasibility of unit cell dimension shrinkage may be increased in 4F2 DRAM. In the cross-sectional view of FIG. 2, a shape of each of the word lines WL1-WL2 is a rectangle with vertical edges.

In FIG. 1, one of the word lines WL1 or WL2 surrounds a group of the oxide semiconductor pillars OS along a direction parallel to a plane (of the substrate 110 of FIG. 2), and the oxide semiconductor pillars OS are disposed vertically to the plane. The gate oxide layer 106 is dispose between each of the oxide semiconductor pillars OS and each of the word lines WL1-WL2. In some embodiments, the vertical channel transistor structure 100 further comprises an insulation layer 108, and a material of the insulation layer 108 may comprises oxide or other suitable insulation materials. The oxide semiconductor pillars OS, the gate oxide layer 106, and the word lines WL1-WL2 may be disposed in the insulation layer 108. In some embodiments, the gate oxide layer 106 is also disposed between each of the oxide semiconductor pillars OS and the insulation layer 108.

FIG. 3 illustrates a cross-sectional view of a vertical channel transistor structure in accordance with some embodiments of the present disclosure. The same reference numerals as the reference numerals used in above embodiments are used to represent the same or similar parts and components, and reference can be made to the related content of above embodiments for the same or similar parts and components and are not be repeated.

In FIG. 3, the vertical channel transistor structures 300 have word lines WL1′ and word lines WL2′, and the shape of each of the word lines WL1′ and the word lines WL2′ is a trapezoid. This inverted trapezoid is obtained by nature etching property, and the minimum distance s3 between the word line WL1′ and the word line WL2′ may be larger than that (the minimum distance s1 of FIG. 2) in above embodiments. In other words, the vertical channel transistor structures 300 may be superior to previous embodiments in term of reducing WL-WL coupling effect.

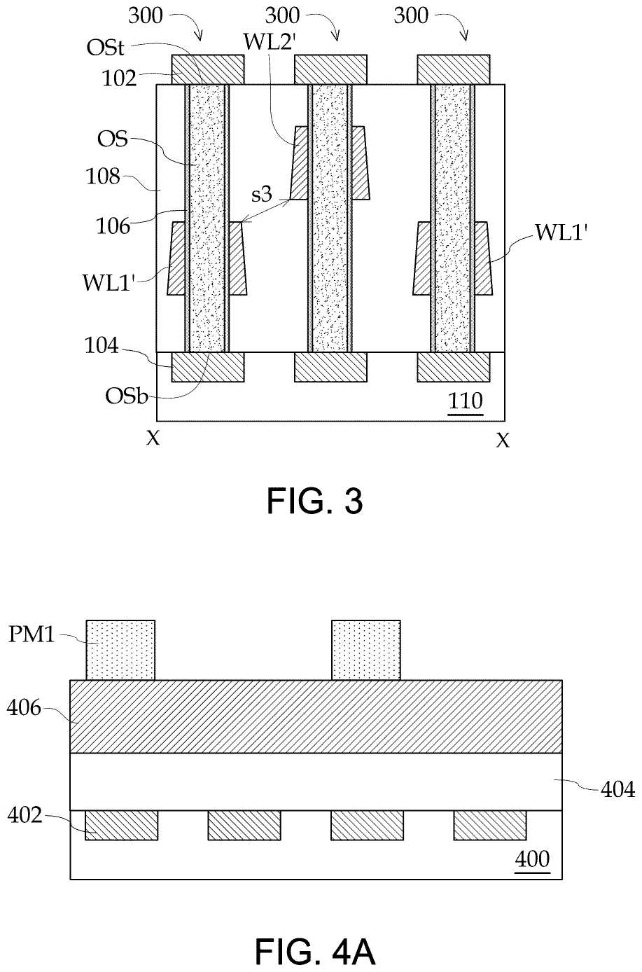

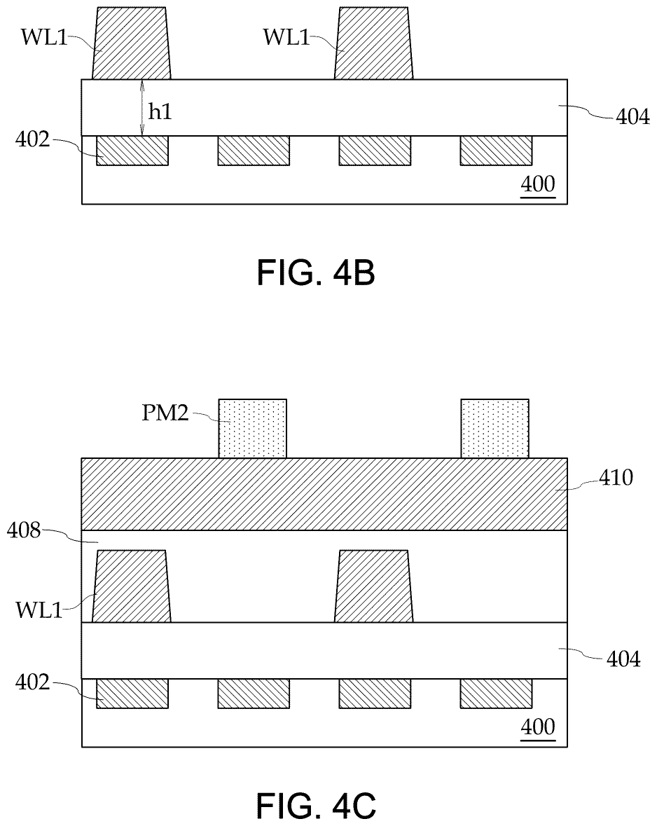

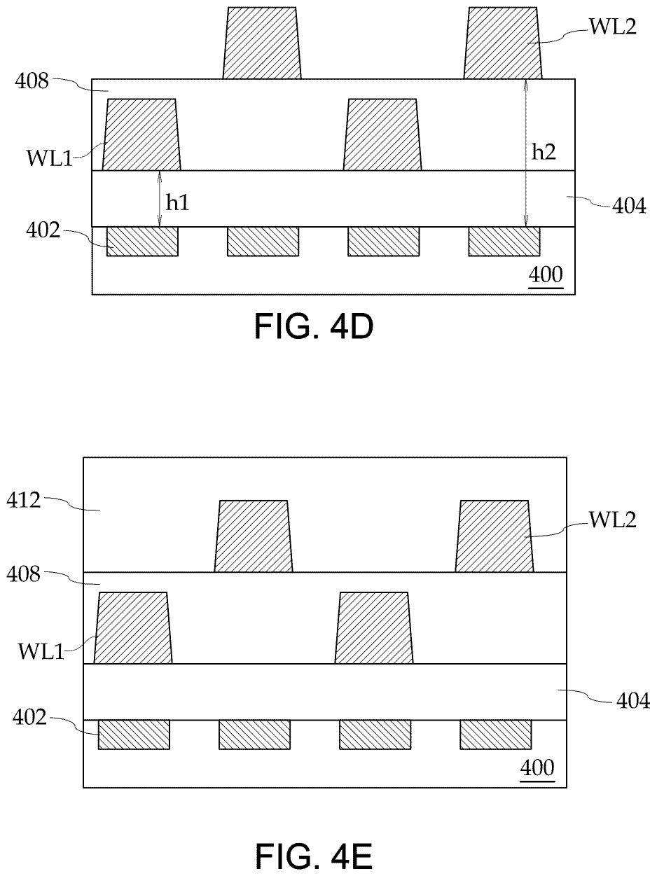

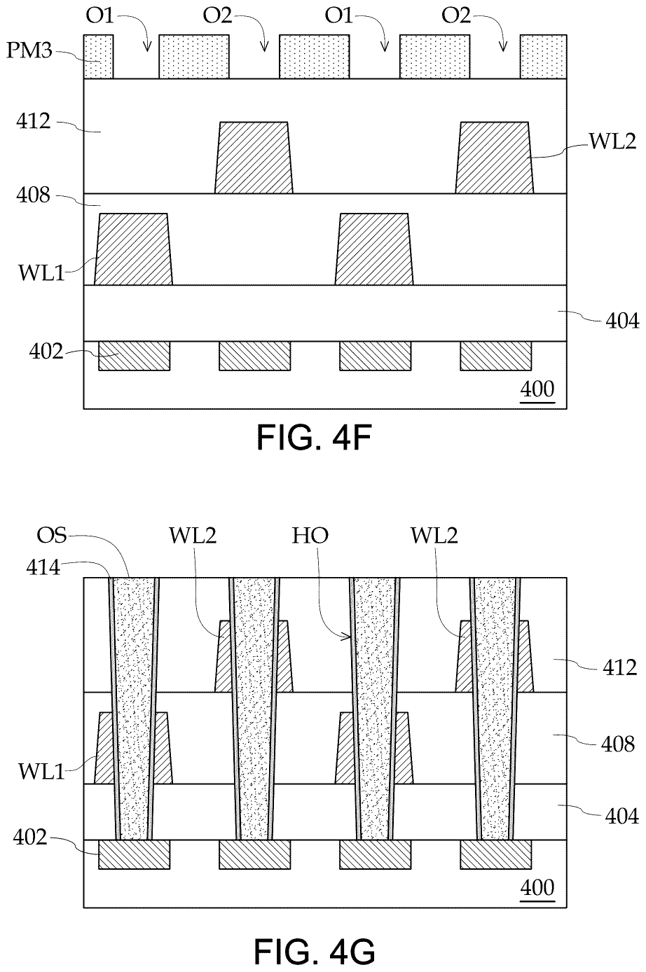

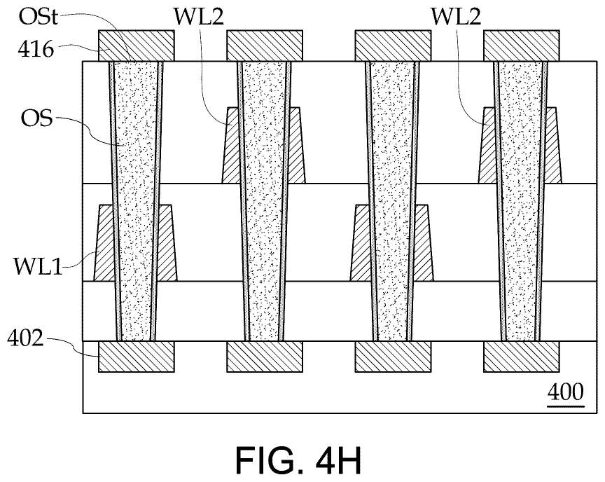

FIG. 4A through FIG. 4H are cross-sectional views of a process for the manufacture of a vertical channel transistor structure in accordance with some embodiments of the present disclosure.

Referring to FIG. 4A, a plurality of first electrodes 402 is formed on a substrate 400. A first insulation layer 404 may be formed on the first electrodes 402, and a conductive material layer 406 is then deposited on the first insulation layer 404. In some embodiments, the first insulation layer 404 may be an oxide or other suitable material. A first patterned mask PM1 is formed on the conductive material layer 406 to expose a portion of the conductive material layer 406. In some embodiments, the first patterned mask PM1 may be a patterned photoresist through an photolithograph process.

Referring to FIG. 4B, the conductive material layer 406 in FIG. 4A is etched back using the first patterned mask PM1 in FIG. 4A as an etching mask, thereby forming first word lines WL1 at a first height h1 over the first electrode 402. Due to the etching property, a profile of two adjacent first word lines WL1 and the first insulation layer 404 therebetween is like an inverted trapezoid. The first patterned mask PM1 in FIG. 4A would be removed later.

Referring to FIG. 4C, a second insulation layer 408 is formed on the first word lines WL1, and a conductive material layer 410 is then deposited on the second insulation layer 408 over the first word lines WL1. In some embodiments, the method for forming the second insulation layer 408 includes depositing an oxide to gap fill and cover the first word lines WL1 followed by CMP. A second patterned mask PM2 is formed on the conductive material layer 410 to expose a portion of the conductive material layer 410. In some embodiments, the second patterned mask PM2 may be a patterned photoresist through an photolithograph process.

Referring to FIG. 4D, the conductive material layer 410 in FIG. 4C is etched back using the second patterned mask PM2 in FIG. 4C as an etching mask, thereby forming second word lines WL2 at a second height h2 over the first electrode 402, wherein the first height h1 is different form the second height h2. In this embodiment, the first height h1 is shorter than the second height h2. Due to the etching property, a profile of two adjacent second word lines WL2 and the second insulation layer 408 therebetween is like an inverted trapezoid. The second patterned mask PM2 in FIG. 4C would be removed later.

Referring to FIG. 4E, a third insulation layer 412 is formed on the second word lines WL2. In some embodiments, the method for forming the third insulation layer 412 includes depositing an oxide to gap fill and cover the second word lines WL2 followed by CMP.

Referring to FIG. 4F, a third patterned mask PM3 is formed on the third insulation layer 412. In some embodiments, the third patterned mask PM3 may be a patterned photoresist through an photolithograph process. The third patterned mask PM3 has first openings O1 aligned with the first word lines WL1. The third patterned mask PM3 has second openings O2 aligned with the second word lines WL2.

Referring to FIG. 4G, using the third patterned mask PM3 in FIG. 4F as an etching mask, the third insulation layer 412, the second word lines WL2, the second insulation layer 408 and the first word lines WL1 are etched until the first electrodes 402 are exposed, thereby forming a plurality of channel holes HO to penetrate the first word line WL1 and the second word line WL2, respectively. After removing the third patterned mask PM3 in FIG. 4F, a gate oxide layer 414 is formed at a sidewall of each of the channel holes HO, and then a plurality of oxide semiconductor pillars OS is formed in the channel holes HO. The oxide semiconductor pillar OS may be in direct contact with the first electrode 402. In some embodiments, a shape of each of the oxide semiconductor pillars OS is an inverted trapezoid.

Referring to FIG. 4H, a plurality of second electrodes 416 is formed on the oxide semiconductor pillars OS, respectively.

In summary, from process point of view, the feasibility of the double deck WLs process is feasible. Also, from the electrical point of view, the WL-WL coupling can be further reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A vertical channel transistor structure, comprising:
a plurality of oxide semiconductor pillars, wherein each of the plurality of oxide semiconductor pillars has a top end and a bottom end;
a first electrode disposed under and connected to the bottom end of each of the plurality of oxide semiconductor pillars;
a second electrode disposed on and connected to the top end of each of the plurality of oxide semiconductor pillars;
a plurality of word lines disposed at different heights of the plurality of oxide semiconductor pillars; and
a gate oxide layer disposed between each of the plurality of oxide semiconductor pillars and each of the plurality of word lines.

2. The vertical channel transistor structure of claim 1, wherein one of the word lines is disposed at different height of the oxide semiconductor pillars with another one of the word lines close to the one of the word lines.

3. The vertical channel transistor structure of claim 2, wherein a minimum distance between the one of the word lines and the another one of the word lines is longer than a horizontal distance between the one of the word lines and the another one of the word lines.

4. The vertical channel transistor structure of claim 1, wherein in a cross-sectional view, a shape of each of the plurality of word lines is a trapezoid.

5. The vertical channel transistor structure of claim 1, wherein in a cross-sectional view, a shape of each of the plurality of oxide semiconductor pillars is an inverted trapezoid.

6. The vertical channel transistor structure of claim 1, wherein one of the plurality of word lines surrounds a group of the plurality of oxide semiconductor pillars along a direction parallel to a plane, and the oxide semiconductor pillars are disposed vertically to the plane.

7. A method of manufacturing a vertical channel transistor structure, comprising:
forming a plurality of first electrodes on a substrate;
forming a first word line at a first height over the first electrode;
forming a second word line at a second height over the first electrode, wherein the first height is different form the second height;
forming a plurality of channel holes penetrating the first word line and the second word line respectively;
forming a gate oxide layer at a sidewall of each of the plurality of channel holes;
forming a plurality of oxide semiconductor pillars in the plurality of channel holes; and
forming a plurality of second electrodes on the plurality of oxide semiconductor pillars respectively.

8. The method of manufacturing the vertical channel transistor structure of claim 7, wherein the first height is higher than the second height.

9. The method of manufacturing the vertical channel transistor structure of claim 7, wherein a method of forming the first word line comprises:
forming a first insulation layer on the plurality of first electrodes;
depositing a conductive material layer on the first insulation layer;
forming a first patterned mask on the conductive material layer; and
etching back the conductive material layer using the first patterned mask as an etching mask.

10. The method of manufacturing the vertical channel transistor structure of claim 7, wherein a method of forming the second word line comprises:
forming a second insulation layer on the first word line;
depositing a conductive material layer on the second insulation layer;
forming a second patterned mask on the conductive material layer; and
etching back the conductive material layer using the second patterned mask as an etching mask.

11. The method of manufacturing the vertical channel transistor structure of claim 7, wherein a method of forming the plurality of channel holes comprises:
forming a third insulation layer on the second word line;
forming a third patterned mask on the third insulation layer; and
etching the third insulation layer, the second word line and the first word line using the third patterned mask as an etching mask until the plurality of first electrodes is exposed.

12. The method of manufacturing the vertical channel transistor structure of claim 11, wherein the third patterned mask has a first opening aligned with the first word line.

13. The method of manufacturing the vertical channel transistor structure of claim 11, wherein the third patterned mask has a second opening aligned with the second word line.
